(19) United States
(12) Patent Application Publication
(10) Pub. No.: US 2024/0063071 A1
(43) Pub. Date: Feb. 22, 2024

(54) INORGANIC MATERIAL DEPOSITION FOR INTER-DIE FILL IN MULTI-CHIP COMPOSITE STRUCTURES

(71) Applicant: Intel Corporation, Santa Clara, CA (US)

(72) Inventors: Jeffery Bielefeld, Forest Grove, OR (US); Adel Elsherbini, Chandler, AZ (US); Bhaskar Jyoti Krishnatreya, Hillsboro, OR (US); Feras Eid, Chandler, AZ (US); Gauri Auluck, Hillsboro, OR (US); Kimin Jun, Portland, OR (US); Mohammad Enamul Kabir, Portland, OR (US); Nagatoshi Tsunoda, Tsukuba-shi (JP); Renata Camillo-Castillo, Portland, OR (US); Tristan A. Tronic, Aloha, OR (US); Xavier Brun, Hillsboro, OR (US)

(73) Assignee: Intel Corporation, Santa Clara, CA (US)

(21) Appl. No.: 17/891,880

(22) Filed: Aug. 19, 2022

(51) Int. Cl. H01L 23/31; H01L 25/065; H01L 23/00; H01L 23/367; H01L 23/498; H01L 21/48; H01L 21/56; H01L 25/00

(52) U.S. Cl. CPC H01L 23/3128; H01L 25/0655; H01L 24/08; H01L 23/367; H01L 23/49827; H01L 23/49838; H01L 21/4853; H01L 21/486; H01L 21/56; H01L 24/80; H01L 25/50; H01L 2224/08225; H01L 2224/80895; H01L 2224/80896

(57) ABSTRACT

Multi-die composite structures including a multi-layered inorganic dielectric gap fill material within a space between adjacent IC dies. A first layer of fill material with an inorganic composition may be deposited over IC dies with a high-rate deposition process, for example to at least partially fill a space between the IC dies. The first layer of fill material may then be partially removed to modify a sidewall slope of the first layer or otherwise reduce an aspect ratio of the space between the IC dies. Another layer of fill material may be deposited over the lower layer of fill material, for example with the same high-rate deposition process. This dep-etch-dep cycle may be repeated any number of times to backfill spaces between IC dies. The multi-layer fill material may then be globally planarized and the IC die package completed and/or assembled into a next-level of integration.

### BACKGROUND

Monolithic integrated circuit (IC) fabrication has restrictions that may limit a final product's performance, and thus different versions of IC die (dis)integration are being investigated. To date however, these techniques and architectures generally suffer from certain drawbacks such as high cost, lower insertion efficiency, and increased z-height.

IC die disintegration techniques rely on advances in multi-die integration at the package level or at one or more levels between monolithic IC die fabrication and the package level. In electronics manufacturing, IC packaging is a stage of semiconductor device fabrication in which an IC that has been monolithically fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled, for example, into a multi-chip package (MCP).

Such multi-chip architectures may advantageously combine IC chips from heterogeneous silicon processes and/or combine small dis-aggregated chips from identical silicon processes. However, there are many challenges with integrating multiple IC die into a chip-scale unit. For example, inter-die fill material, such as an epoxy-based mold material can introduce high stress that causes a mechanical reliability problem as the thickness of multi-die structures is reduced.

Accordingly, alternative fill materials in multi-die composite chip architectures, and fabrication techniques associated with those architectures, may be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a multi-chip composite device structure including multilayered inorganic dielectric fill structures, in accordance with some embodiments;

FIG. 2A is a cross-sectional view of a host substrate including metallization features, in accordance with some embodiments;

FIG. 2B is a plan view of the host substrate illustrated in FIG. 2A, in accordance with some embodiments;

FIG. 3A is a cross-sectional view of IC dies being placed on a host substrate, in accordance with some embodiments;

FIG. 3B is a cross-sectional view of IC dies bonded into a multi-chip composite structure, in accordance with some embodiments;

FIG. 3C is a plan view of the multi-chip composite structure illustrated in FIG. 3B, in accordance with some embodiments;

FIG. 4A is a cross-sectional view of an inorganic dielectric material layer deposited over adjacent IC dies and within a space between adjacent IC dies, in accordance with some embodiments;

FIG. 4B is a cross-sectional view of an inorganic dielectric material layer following an etchback process, in accordance with some embodiments;

FIG. 4C is a cross-sectional view of another inorganic dielectric material layer deposited over adjacent IC dies and within a space between adjacent IC dies, in accordance with some embodiments;

FIG. 5A is a cross-sectional view of a multi-layered inorganic die gap fill planarized with adjacent IC dies, in accordance with some embodiments;

FIG. 5B is a plan view of the planarized multi-layered inorganic die gap fill illustrated in FIG. 5A, in accordance with some embodiments;

FIG. 6A is a cross-sectional view of a multi-chip composite structure after stacking an additional component upon adjacent IC die, in accordance with some embodiments;

FIG. 6B is a cross-sectional view of a multi-chip composite structure with interconnect features coupled to through vias that are embedded within a base substrate, in accordance with some embodiments;

FIG. 7 illustrates a system including the multi-chip composite structure illustrated in FIG. 6B attached to a host component with FLI features, in accordance with some embodiments;

FIG. 8 illustrates a mobile computing platform and a data server machine employing a multi-chip composite including a multi-layered inorganic die gap fill, in accordance with some embodiments; and

FIG. 9 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Integrated die structures including multiple IC die bonded to a host substrate and covered with a multiple inorganic gap filling material layers are described herein. These structures may be referred to as a “composite” because at least some of the IC dies are directly bonded to the host substrate rather than being interconnected with a joining material, such as solder. Such composite structures may also be referred to as quasi-monolithic as the inorganic fill material layers provided herein are more like the materials found in monolithic ICs than those found in IC die packages, which are typically organic materials.

For bonded IC dies where metal features of the host substrate are fused to those of the IC die, the resulting composite, quasi-monolithic structure may comprise a hybrid bonded interface of both metallurgically interdiffused metals and chemically bonded insulators. Prior to IC die bonding, each (active) IC die may be fabricated in a monolithic process separate from each other. As such, each IC die may be fabricated with the same or different wafer fab technologies. Each IC die may be fabricated to support face-to-face, face-to-back, or back-to-back bonding with another IC die.

After bonding the IC dies, inorganic gap fill material layers may be deposited with techniques that efficiently achieve a fill thickness comparable to that of the IC die(s). After depositing a first inorganic material layer, an etch process may be performed to modify a sidewall slope of the inorganic material layer to be more sloped from perpendicular to a substrate plane than an edge sidewall of the IC die(s). Following the etch back process, another inorganic material layer may be deposited, forming an interface with the first inorganic material layer that has the modified sidewall slope. After any number of such dep-etch-dep cycles, a global planarization process may be performed.

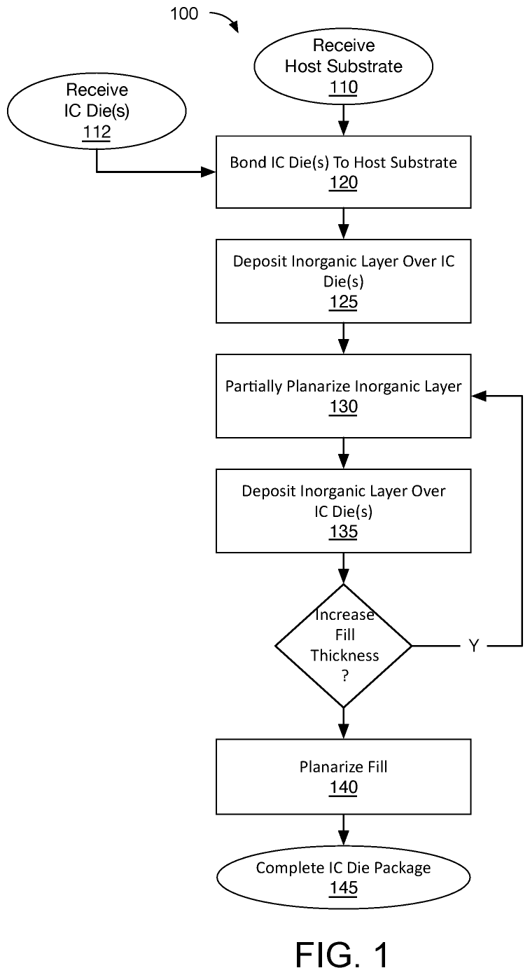

A number of different fabrication methods may be practiced to form a composite IC die structure having one or more of the features or attributes described herein. FIG. 1 illustrates a flow diagram of methods 100 for forming a composite IC die structure including a multi-layered inorganic gap fill material, in accordance with some embodiments.

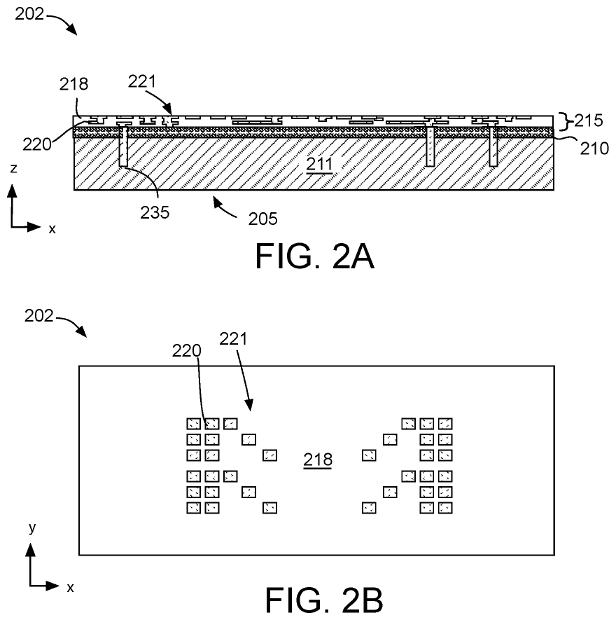

Methods 100 begin at input 110 with the fabrication of a host substrate or the receipt of a host substrate that has been fabricated upstream of methods 100. The host substrate may be any IC die, interposer, or package substrate suitable for a multi-chip composite architecture. In the example illustrated in FIGS. 2A and 2B, a host substrate 202 has a back side 205 comprising a substrate material 211. In some examples, substrate material 211 is silicon. In other examples, substrate material 211 is an alternative crystalline material, such as, but not limited to, germanium, SixGel, GexSm, or silicon carbide. In still other examples, substrate material 211 is a glass (e.g., silica), which can have flatness approximately equal to that of crystalline substrates, but at a lower cost.

In some embodiments, host substrate 202 is an “active” IC die and includes a device layer 210 fabricated in, or on, substrate material 211. Device layer 210 may be homogenous with substrate material 211, or not (e.g., a transferred substrate). Device layer 210 (and a homogeneous IC die substrate material 211) may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, IC device layer 210 is a Group III-V material comprising a Group III majority constituent and a Group IV majority constituent (e.g., InGaAs, GaAs, GaSb, InGaSb). IC die device layer 210 may have a thickness of 50-1000 nm, for example. IC die device layer 210 need not be a continuous layer of semiconductor material, but rather may include active regions of semiconductor material surrounded by field regions of isolation dielectric.

In some embodiments, the active devices within device layer 210 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die device layer 210 may include active devices other than FETs. For example, IC die device layer 210 may include electronic memory structures, such as magnetic tunnel junctions (MTJs), capacitors, or the like.

In alternative embodiments, host substrate 202 is “passive” and lacks device layer 210. Regardless of whether host substrate 202 is active or passive, host substrate 202 may include passive devices such as resistors, capacitors, or inductors (not depicted).

Host substrate 202 has a front side 221 that comprises one or more metallization levels 215. In exemplary embodiments, metallization levels 215 include metallization features 220 embedded within an insulator 218. While metallization features 220 may have any composition(s) of sufficient electrical conductivity, in exemplary embodiments, metallization features 220 are predominantly copper (Cu). In other examples, metallization features 220 are predominantly other than Cu, such as, but not limited to predominantly Ru, or predominantly W. An uppermost one of metallization layers 215 includes “bondable” metallization features 220 that have an associated feature pitch suitable for directly bonding to complementary conductive features of an IC die. This feature pitch may range from 100 nm to several microns, for example. In the illustrated example, host substrate further includes TSVs 235 extending into substrate material 211. As described further below, a composite device structure may be subsequently thinned by removing at least some of substrate material 211 to expose TSVs 235.

Insulator 218 may have any composition(s) suitable as an electrical insulator. In exemplary embodiments, insulator 218 is an inorganic interlayer dielectric (ILD) material having any material composition known to be suitable as an insulator of monolithic integrated circuitry, such as, but not limited to, silicon dioxide, silicon nitride, silicon oxynitride, or a low-k material having a relative permittivity below 3.5. In some embodiments, ILD materials vary in composition with a lower ILD material layer 218 comprising a low-k dielectric material and an uppermost ILD material layer 218 comprising a conventional dielectric material (e.g., having a dielectric constant of approximately 3.5, or more). Confining low-k dielectric materials distal from a bond interface in this manner may advantageously improve bond strength and/or quality. In other embodiments where low-k dielectric material can form a strong bond interface, all ILD material layers 218 may all be a low-k material (e.g., having a relative permittivity of 1.5-3.0).

Returning to FIG. 1, methods 100 continue with the receipt of one or more IC dies at input 112. Each IC die may have been fabricated upstream of methods 100 according to any technique known. Each IC die received at input 112 may be a fully functional ASIC, or may be a chiplet or tile having a more limited functionality that supplements the function of one or more other IC dies, chiplets or tiles. A chiplet or tile may, for example, be any of a wireless radio circuit, microprocessor core, electronic memory circuit, floating point gate array (FPGA), power management and/or power supply circuit, or include a MEMS device.

At block 120, IC dies are bonded to the host substrate in a stack-up to form a composite device structure comprising one or more IC dies on the host substrate. Bonding of an IC die may be according to any alignment and bonding process suitable for the IC die and host substrate. For example, an IC die of a relatively large edge length may be handled and aligned to a target location on the host substrate according to pick-and-place die assembly methods and systems. Many such methods and systems can handle an object as thin as 10-100 μm and with sidewall edge length ranging from tens of millimeters down to ˜200 μm. Die attachment may also comprise one or more micro device assembly techniques including so-called transfer printing methods, which can accommodate an object as thin as 1 μm and having lateral dimensions in the tens of micrometers. Such micro device assembly techniques may rely on a MEMS microtool that includes hundreds or even thousands of die attachment points. Micro device assembly methods and systems suitable for inorganic LED (iLED) technology, for example, may be employed to transfer a plurality of IC chiplets concurrently from a source IC die substrate to multiple host substrates arrayed within a wafer or panel.

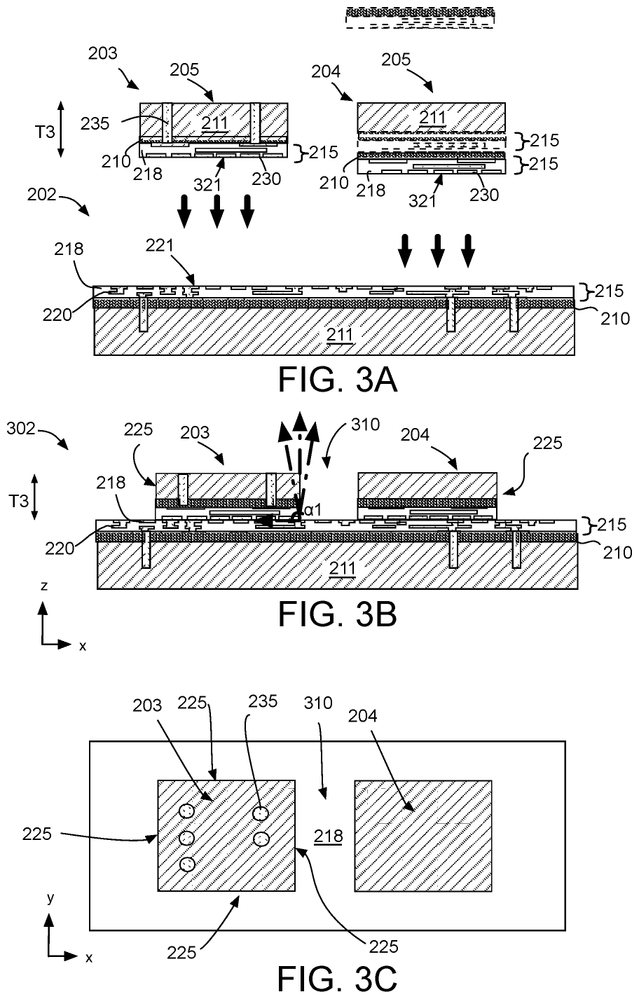

In the example further illustrated in FIG. 3A, IC die 203 and IC die 204 are aligned for bonding with metallization features on host substrate front side 221. IC dies 203, 204 may be “face-to-face” bonded where features on a front-side of IC dies 203, 204 are bonded to features on a front-side of host substrate 202. In alternative embodiments, IC dies 203, 204 may be “face-to-back” or “back-to-face” bonded to host substrate 202.

Each of IC die 203 and IC die 204 may have any circuit functionality and any structure. In some other examples, IC dies 203 or 204 include one or more banks of active repeater circuitry to improve multi-chip interconnects (e.g., network-on-chip architectures). A repeater bank may, for example, support 2000+ signals within an IC die area of 0.4 mm². In other examples, IC die 203 or IC die 204 includes clock generator circuitry or temperature sensing circuitry. In other examples, IC die 203 or IC die 204 includes one or more ESD banks. In other examples, IC die 203 or IC die 204 includes logic circuitry that, along with other IC die implements 3D logic circuitry (e.g., mesh network-on-chip architectures). In still other examples, at least one of IC die 203 or IC die 204 includes microprocessor core circuitry, for example comprising one or more shift registers.

As shown in FIG. 3A, IC die 203 and IC die 204 have a sidewall edge thickness T3, which may vary with implementation. In some examples, sidewall edge thickness T3 is in the range of 10-200 μm. IC dies 203, 204 each include one or more device layers 210 over substrate material 211. Each device layer 210 is interconnect into circuitry with backend metallization levels 215. A device level 210 and metallization level 315 are illustrated in solid line to be the front side 321. IC die 204 further includes another device level 210 and metallization level 315 shown in dashed line to represent a stacked die embodiment. Device layer 210, substrate material 211 and metallization levels 215 may have any of the properties described above for those embodiments where host substrate 202 is also an IC die. In the illustrated arrangement, front side 321 of IC dies 203, 204 are to bond with host substrate front side 221 in a face-to-face configuration. In the illustrated example, IC die 203 further includes TSVs 235 extending through IC die substrate material 211 while IC die 204 illustrates an alternative lacking such die-level TSVs.

The arrows in FIG. 3A represent a positional alignment of bondable metal features on host substrate 202 to corresponding metal features on IC dies 203, 204. The feature pitch at the bond interface accommodates alignment imprecision. The feature pitch of the metal features on IC dies 203, 204 and host substrate 202 may therefore be predetermined based on alignment capabilities of a particular bonder.

FIG. 3B illustrates a cross-sectional view of a multi-chip composite IC die structure 302 following hybrid bonding of IC dies 203, 204 to host substrate 202 so that the IC dies 203, 204 are adjacent to each other with a gap or space 310 between their nearest edge sidewalls 225. Notably, in addition to comprises an IC die stack one or more of IC dies 203, 204 may be a multi-chip composite IC die structure including multiple IC dies bonded to a host or base substrate substantially as illustrated in FIG. 3B. For such embodiments, one or more of IC dies 203, 204 may be substituted with multi-chip composite IC die structure 302 so that multi-chip composite IC die structure includes another multi-chip composite IC die structure. Hence, FIG. 3B illustrates the basic elements to a multi-chip composite IC die structure which can become a element of another multi-chip composite IC die structure, etc.

The hybrid bonding surfaces of IC dies 203-204 are substantially co-planar. IC dies 203, 204 may be aligned to a target location on host substrate 202 with any high-resolution alignment tool, for example of the type found on a wafer-level or chip-level bonding tool commercially available through a number of industry suppliers. Alignment capability continues to advance, having improved from +/−5 μm to +/−0.2 μm over recent years. Once adequately aligned, and direct bonding technique(s) suitable for the IC die and host substrate may be practiced. Direct bonding of host substrate 202 to IC dies 203, 204 may be metal-to-metal, for example, during which metallization features sinter. In some embodiments, a hybrid bond is formed both between metallization features (e.g., via metal interdiffusion) and between dielectric materials (e.g., via Si—O—Si condensation bonds). Thermo-compression bonding may be at low temperature (e.g., below melting temperature of the interconnects, and more specifically below 100° C.). Direct bonding at room temperature (i.e., compression only) is also possible. Prior to bonding, any of host substrate 202 or IC dies 203, 204 may be pre-processed, for example with a plasma clean, to activate their surfaces for the bonding. Post bonding, selective heating may be performed to make permanent the bond (e.g., by converting a van der waals bond into a metallic bond between the conductive pads through interdiffusion). For selective heating, a laser, magnetic or electromagnetic radiation may be employed to limit heating to a specific one IC die 203, 204. The figure shows dies 203 and 205 as single dies but they may also consist of two or more bonded dies (multiple active layers, metallization layers, bonding layers and through-substrate-vias). They may also consist of composite dies (e.g., a base die with multiple dies attached to it). Furthermore, to accommodate the mechanical and processing requirements, one or more of the dies 203 or 204 may be a dummy die (e.g., a substrate with bonding layer only and no additional routing layers or active devices).

In some embodiments, lateral (e.g., x-axis) misalignment or misregistration between conductive features of host substrate 202 and IC dies 203, 204 is less than 0.2 μm. For example, lateral misalignment between one conductive feature (e.g., a line or trace) and another conductive feature (e.g., a via) within one monolithic IC die may be at least an order of magnitude smaller than the lateral misalignment between bonded conductive features. The lateral dimensions of metallization features at the bond interface are sufficiently large to accommodate such lateral offset. Where multiple IC die 203 and IC die 204 are bonded individually to host substrate 202, the magnitude of the lateral offset may vary between the IC die.

As shown in the cross-sectional view of FIG. 3B, IC die 203 has an edge 225 with a sidewall slope associated with angle α1, relative to an x-y plane of substrate 202. Illustrated by arrows, sidewall slope associated with angle α1 from an x-y plane co-planar with the bond interface between IC die 203 and host substrate 202 may vary, for example over some range slightly above and below 90° (i.e., perpendicular to x-y plane). In some examples, IC die edge 225 has a sidewall slope that is within 10° of normal to an x-y plane of host substrate surface 221. In other examples, IC die edge 225 may have a sidewall slope that deviates up to 40° from perpendicular to an x-y plane of host substrate surface 221. Although not illustrated, IC die 204 also has an edge 225 with some sidewall slope, which may be substantially the same as, or significantly different from, that of IC die 203.

As shown in the plan view of FIG. 3C, IC die edge 225 is a perimeter edge defining a footprint or area of IC die 203. Sidewall slope of die edge 225 may vary along the IC die perimeter (e.g., angle α1 varying along the length of edge 225), as embodiments herein are not limited in this respect. As shown in FIGS. 3B and 3C, inter-die space 310 may vary depending on clearance needed for die alignment, for example from 5-50 μm. Accordingly, the aspect ratio of space 310 may vary with as a function of die bonding and the sidewall slope of adjacent portions of die edges 225. The dies are illustrated as having rectangular shape, however any suitable shape is possible. For example, dies may have triangular, hexagonal or octagonal shapes. They may also have rectangular shape with chamfered or filleted edges.

Returning to FIG. 1, methods 100 continue with the formation of fill material over the one or more IC dies bonded to the host substrate. In exemplary embodiments, a first layer of inorganic material is deposited at block 125. Relative to organic material (e.g., comprising an epoxy), inorganic material is advantageous for its lower stress and/or higher modulus enabling improved overall structure reliability and mechanical stability and/or better CTE match with IC die and/or lower dielectric constant and/or higher thermal conductivity. At block 125, a first layer of inorganic material is deposited directly upon the bonded IC die, for example with any deposition technique suitable for monolithic IC fabrication. In some embodiments, an inorganic material is deposited with chemical vapor deposition (CVD), which may be plasma enhanced (PECVD) and/or comprise a high-density plasma process (HDP-CVD). Such processes may enable fast deposition at low temperatures but they do not offer good gap filling performance due to pinch off and shadowing effects especially where the aspect ratio of the gap or space between adjacent dies exceeds 1:1.

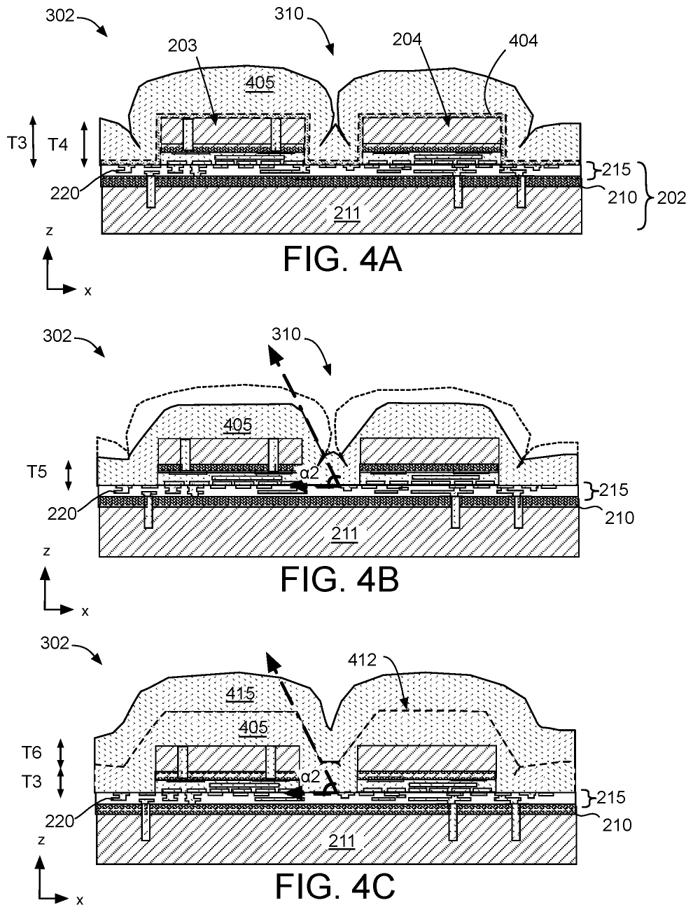

In the example illustrated in FIG. 4A, composite IC die structure 302 now includes an inorganic fill material layer 405, which has been deposited over IC dies 203, 204 and exposed regions of host substrate 202. Inorganic fill material layer 405 has an as-deposited thickness T4, which may vary with implementation. In the illustrated embodiment, as-deposited thickness T4 is less than the IC die thickness T3. In some examples, as-deposited thickness T4 is in the range of 10-80 μm.

Inorganic fill material layer 405 may have any composition known to be suitable for gap fill in the context of monolithic IC fabrication. In exemplary embodiments, inorganic fill material layer 405 is a dielectric material. Exemplary inorganic dielectric materials may comprise predominantly silicon and oxygen. In some embodiments, inorganic fill material layer 405 is substantially SiO₂. In other embodiments, inorganic fill material layer 405 comprises significant, hydrogen, nitrogen and/or carbon content (e.g., SiN, SiC, SiON, SiOC, SiONC, α-C, etc.).

In some embodiments, an adhesion, barrier, mechanical buffer or interface material layer 404 is deposited prior to the deposition of inorganic fill material layer 405. Adhesion material layer 404 is illustrated in dashed line to emphasize that it is optional. For embodiments lacking material layer 404, inorganic fill material layer 405 is in direct contact with IC dies 203, 204 and host substrate 202. If present, material layer 404 may be either an organic or inorganic material and is advantageously a dielectric material. In some exemplary embodiments where material layer 404 is an inorganic dielectric material, material layer 404 comprises silicon and at least one of oxygen and nitrogen. In some examples, material layer 404 comprises more nitrogen than inorganic fill material layer 405. For example, material layer 404 may advantageously comprise predominantly silicon and nitrogen (e.g., SiN) while inorganic fill material layer 405 comprises predominantly silicon and oxygen (e.g., SiO). In other embodiments, the layer 404 may be replaced with a multi-layered stack to, e.g., improve performance and/or mechanical properties.

Interface material layer 404 may have any thickness, but in the illustrated example is substantially thinner than thickness T4 of inorganic fill material layer 405, e.g., between 10 nm and 1000 nm. Adhesion material layer 404 is advantageously deposited with a highly conformal CVD process that ensures material layer 404 has thickness conformality exceeding that of inorganic fill material layer 405. The higher thickness conformality of material layer 404 may be achieved through a slower deposition process, for example, and/or with precursors, process temperatures or process pressures that promote higher surface mobility, etc.

In the presence of a dielectric adhesion material layer 404 with good step coverage, inorganic fill material layer 405 need not be relied upon for electrical isolation of adjacent IC dies 203, 204 and so may be other than a dielectric material. For example, inorganic fill material layer 405 may be a semiconductor (e.g., substantially amorphous silicon, germanium, or SiGe) or a conductor (e.g., a metallic compound, graphite, etc.). Relative to dielectric material embodiments, such inorganic materials may, for example, improve thermal conductivity of composite IC die structure 302.

For greater deposition rates, inorganic fill material layer 405 may be more non-conformal and/or display topographic shadowing effects. As shown in FIG. 4A, for example, inorganic fill material layer 405 has some cusping and/or “bread loafing” as a result of underlying IC die thickness T3, and a nearly perpendicular die edge sidewall slope that reduces the rate of deposition upon IC die edges 225 and within the space between the IC dies relative to the top of the IC dies 203, 204. At some critical width of space 310 for a given die thickness T3, inorganic fill material layer 405 will pinch off at the top before completely filling space 310.

Methods 100 (FIG. 1) continue at block 130 where a partial, or localized, planarization process is performed. The process(es) performed at block 130 may be any that can modify the sidewall slope of the inorganic fill material layer, or one that partially removes the top of the inorganic fill dielectric, to reduce the aspect ratio of the gaps. In exemplary embodiments, the sidewall slope of the inorganic fill material layer is made more non-perpendicular. In terms of an inside corner angle, the slope of the inorganic fill material layer is modified to be less the edge sidewall slope of at least one IC die covered by the inorganic fill material layer. In terms of the complementary, outside angle, the slope of the inorganic fill material layer is modified to exceed the edge sidewall slope of at least one IC die covered by the inorganic fill material layer.

In some embodiments, a plasma etch process is performed at block 130. The plasma etch process may employ one or more source gases capable of etching the inorganic fill material layer. In exemplary embodiments where the inorganic fill material layer comprises silicon and oxygen, the source gas may comprise fluorine (e.g., NF₃, SF₆, CF₄, etc.). In further embodiments where an inorganic fill material layer is deposited by (HD)PECVD, the plasma etch process may be performed in-situ within the deposition chamber by using a remote/downstream plasma source energized, for example with a magnetron. Alternatively, the etch process may be performed ex-situ of the deposition chamber.

In alternative embodiments, a sputter (e.g., Ar) process is performed at block 130, which can also increase the sidewall slope of the inorganic fill material layer. In still other embodiments, a planarization process is performed at block 130 to polish back a top portion of the inorganic fill material layer. Such planarization can also increase the sidewall slope of the inorganic fill material layer by removing bread-loafed portions of the layer that have a re-entrant)(>90° sidewall slope. The planarization process may comprise a mechanical component such as mechanical grinding or chemical mechanical polishing (CMP) that removes the top few microns of the dielectric and exposes pinched-off regions so they can be subsequently filled with another inorganic fill process.

In the example illustrated in FIG. 4B, a partial thickness of fill material layer 405 has been etched back from as-deposited thickness T4 demarked by a dashed outline to the solid line associated with recessed thickness T5. Advantageous etch processes decrease the sidewall slope of an inside corner angle α2 by as much as possible while retaining as much of the as-deposited thickness T4 as possible. As shown in FIG. 4B, sidewall slope angle α2 is significantly smaller than IC die edge slope angle α1. In exemplary embodiments, sidewall slope angle α2 deviates from the IC die edge slope angle α1 by at least 10°. In terms of the illustrated inside corner, sidewall slope angle α2 is smaller than IC die edge slope angle α1. Hence, for embodiments, where IC die sidewall slope angle α1 is at least 90°, the sidewall slope angle α2 is not more than 80°. Sidewall slope angle α2 may also be smaller than 80° (e.g., 45°-75°). Alternatively, the illustrated slope modification may also be referred to as a slope increment from the IC die sidewall angle if described terms of outside angles that are the complement to the illustrated angles α1 and α2.

Although recessed thickness T5 may vary with implementation, in some exemplary embodiments no portion of an IC die is exposed during the recess etch of inorganic fill material layer 405. Notably, for embodiments including an adhesion layer under of fill material layer 405, the recess etch process may be selective to fill material layer 405 and stop on the underlying adhesion layer. For examples, a plasma etch process tuned for recess etching silica can stop on an adhesion layer of silicon nitride.

Returning to FIG. 1, methods 100 continue at block 135 where another inorganic fill material layer is deposited. In exemplary embodiments, the same deposition process practiced at block 125 is repeated at block 135. This second deposition may, for example, deposit substantially the same material deposited at block 125. Alternatively, different deposition parameters may be enlisted at block 135 so that the additional inorganic fill material layer has a different chemical composition and/or different intrinsic stress (compressive or tensile) than the previously deposited inorganic fill material layer. Because the sidewall slope of the underlying fill material layer was modified, the deposition performed at block 135, even if identical to that performed at block 125, can achieve a better gap fill than what would otherwise be possible in absence of the recess etch at block 130.

In the example further illustrated in FIG. 4C, composite IC die structure 302 further includes an inorganic fill material layer 415 over inorganic fill material layer 405. In some embodiments, inorganic fill material layer 415 has substantially the same chemical composition as inorganic fill material layer 405. Despite compositional homogeneity, an interface 412 is evident between the two layers 405 and 415. Interface 412 may be associated with dangling bonds or other surface defects/states less prevalent within the bulk of fill material layers 405 and 414. As shown, interface 412 displays a sidewall slope associated with angle α2 indicative of the recess etch. The as-deposited thickness T6 may vary with implementation. In some exemplary embodiments, thickness T6 is substantially equal to as-deposited thickness T4. In other embodiments, thickness T6 is substantially equal to recessed thickness T3, or is between T3 and T4.

In some embodiments, inorganic fill material layer 415 has a different chemical composition than inorganic fill material layer 405. For such embodiments, interface 412 demarks a compositional change detectable with one or more chemical analysis techniques sensitive to any constituents that vary between fill material layer 405 and 415. As one example, inorganic fill material layer 415 may have more nitrogen than inorganic fill material layer 405. Hence, where fill material layer 405 is SiO, inorganic fill material layer 415 may be SiON, SiN, SiCN, etc. Inorganic fill material layer 415 may also have a film stress complementary to, or opposite from, that of inorganic fill material layer 405. Differences in stress between fill material layers 405 and 415 may, for example, minimize the cumulative stress of the fill material thickness T3+T6.

Returning to FIG. 1, methods 100 may continue with any number of additional iterations of blocks 130 and 135 to increase the fill thickness, for example to a point where a space between adjacent IC die is completely backfilled. For embodiments where at least a second iteration is performed, the inorganic fill material layer deposited at block 135 is similarly recess etched to again modify the sidewall slope of the thin film. The recess etch may, for example, be substantially the same as the prior iteration where the multiple layers of fill material all have the same chemical composition. Alternatively, each recess etch iteration may be specific to the chemical composition of the fill material layer last deposited.

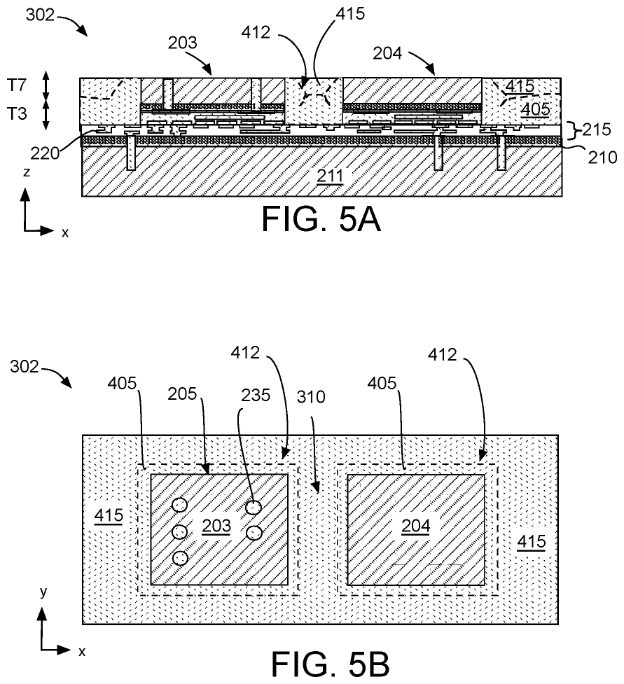

Methods 100 then continue at block 140 where the fill is globally planarized, for example over a significantly longer planarization length than possible with the recess etch performed at block 130. The fill material may be planarized to a surface of one or more of the IC dies embedded within the fill material, for example. Such planarization may retain most of the first inorganic fill material while an upper layer of the fill material may be almost completely removed. In the example further illustrated in FIG. 5A, a grind, polish, or other planarization process has removed an overburden of the inorganic fill material layer 415 to expose surfaces of each of IC dies 203, 204. Notably, at least a portion of interface 412 remains wherever some region of inorganic fill material layer 415 is retained. As further shown in the plan view of FIG. 5B, a retained portion of inorganic fill material layer 415 surrounds two exposed regions of inorganic fill material layer 405 that separately surround the perimeter edges of each of IC dies 203, 204. Following planarization, the fill structure comprising at least material layers 405 and 415 has a final thickness of T3+T7, which is substantially equal to a final thickness of IC die 203 and/or IC die 204.

Returning to FIG. 1, methods 100 continue at output 145 where the composite IC die structure is completed. In some examples, completion of the composite IC die structure comprises the fabrication of one or more metallization features, such as through vias, within the fill (not depicted). The fabrication of through vias may, for example, comprise a patterned etch process that forms via openings into the inorganic fill material(s) and a metal deposition process that fills the via openings with a metal. Such processing is optional, however, and may be excluded from the practice of methods 100.

In some embodiments, completion of the composite IC die structure entails stacking another level of IC dies upon one or more of the IC dies already in the composite structure. In some specific embodiments, completion of the composite IC die structure comprises one or more additional iterations of blocks 125-135 where another level of IC die(s) is similarly gap filled.

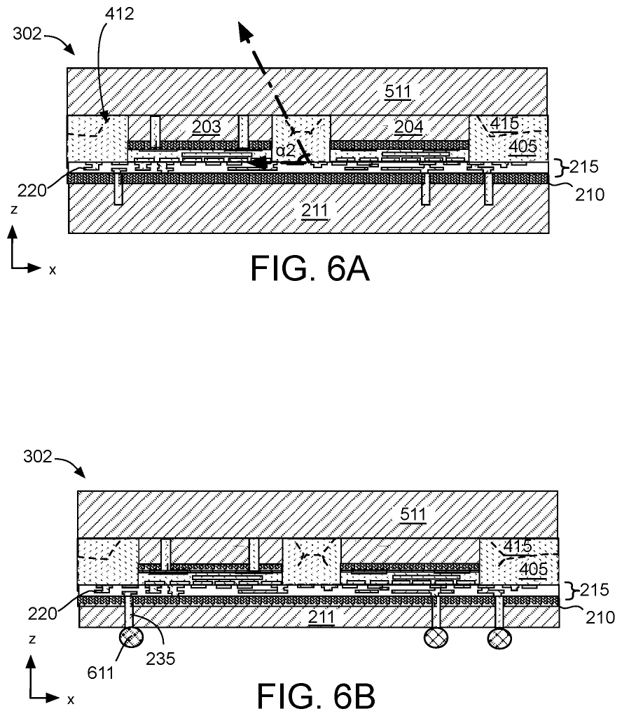

In other embodiments, completion of the composite IC die structure comprises stacking a purely structural member upon one or more lower-level IC dies 203, 204 and/or the surrounding die gap fill. In the example further illustrated in FIG. 6A, a structural member 511 has been bonded to fill material layers 405 and/or 415. Structural member 511 may also be directly bonded to IC dies 203, 204. Unlike another IC die, structural member 511 is for mechanical support alone and is completely passive with no active devices (e.g., transistors). Although the composition of structural member 511 may vary, in some embodiments structure member 511 is monocrystalline silicon. In other embodiments, structural member 511 is a glass (e.g., silica). In still other embodiments, structural member 511 is a preform with an electrically conductive material (e.g., contiguous metal foil, patterned metal routing, etc.).

Following the completion of a composite IC die structure in accordance with embodiments herein, first level interconnects (FLI) may be formed on exposed surfaces of conductive features of the composite structure in preparation for packaging or assembly. In exemplary embodiments, solder features are formed as the FLI. The composite IC die structure may be singulated (before or after forming FLI) according to any techniques known to be suitable for IC die packages. FIG. 6B illustrates one example where host substrate material 211 is thinned to expose through vias 235. FLI interconnects 611 may be coupled to through vias 235 according to any suitable technique as embodiments herein are not limited in this context.

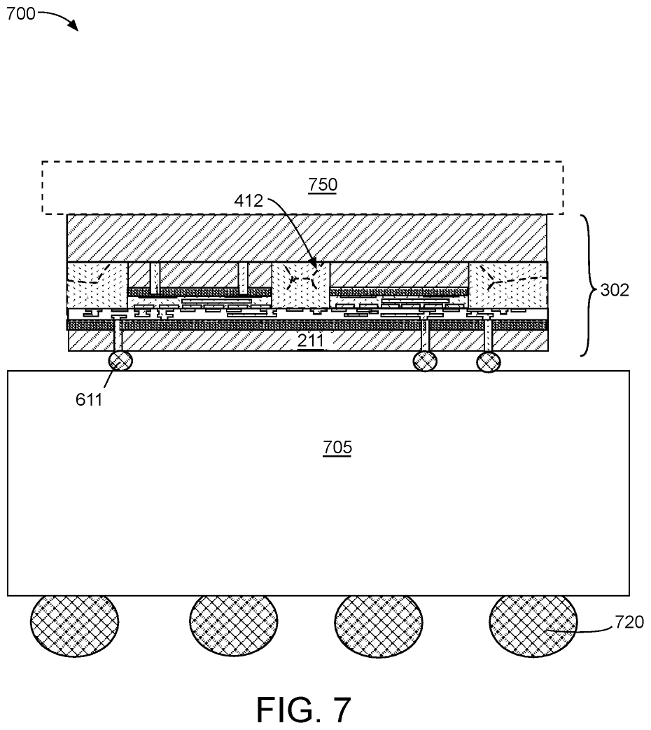

FIG. 7 illustrates a system including IC die composite structure 302 attached to a host component 705 by reflowing FLI interconnects 611. In exemplary embodiments, FLI interconnects 611 are solder (e.g., SAC) microbumps although other interconnect features are also possible. In some embodiments, host component 705 is predominantly silicon. Host component 705 may also comprise one or more alternative materials known to be suitable as interposers or package substrates (e.g., an epoxy preform, cored or coreless laminate board, etc.). Host component 705 may include one or more metallized redistribution levels (not depicted) embedded within a dielectric material. Host component 705 may also include one or more IC die embedded therein. For example, an IC interconnect bridge (not depicted) may be embedded within metallized redistribution levels of host component 705, for example to electrically couple composite IC die structure 302 to another IC die or composite IC die structure.

As further shown in FIG. 7, host component 705 (e.g., a package substrate) may be further coupled system-level host, such as a mother board or other PCB, by second level interconnects (SLI) 720. SLI 720 may comprise any solder (ball, bump, etc.) suitable for a given host board architecture (e.g., surface mount FR4, etc.). As illustrated in dashed line, one or more heat spreaders and/or heat sinks 750 may be further coupled to composite IC die structure 302, which may be advantageous, for example, where composite IC die structure 302 comprises one or more CPU cores or other IC die of similar power density.

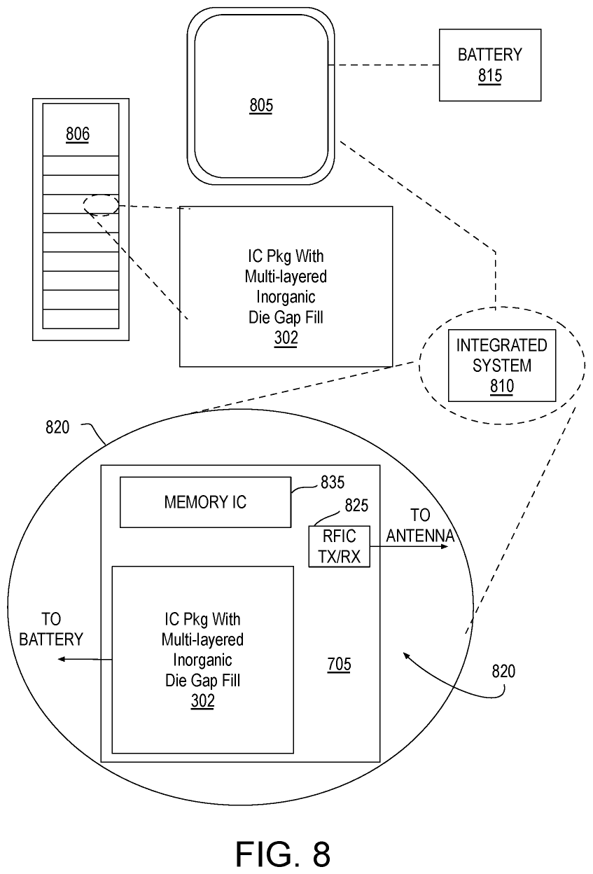

FIG. 8 illustrates a mobile computing platform 805 and a data server machine 806 employing a composite IC die structure including a multi-layered inorganic die gap fill, for example as described elsewhere herein. Server machine 806 may be any commercial server, for example including any number of high-performance computing platforms disposed within a rack and networked together for electronic data processing, which in the exemplary embodiment includes composite IC die structure 302 that further includes a multi-layered inorganic die gap fill, for example as described elsewhere herein. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), an integrated system 810, and a battery 815.

As illustrated in the expanded view 820, composite IC die structure 302 is further coupled to host component 705, along with one or more memory IC 835. One or more of a power management integrated circuit (PMIC) 830 or RF (wireless) integrated circuit (RFIC) 825 including a wideband RF (wireless) transmitter and/or receiver may be further coupled to host component 705. PMIC 830 may perform battery power regulation, DC-to-DC conversion, etc., and so has an input coupled to battery 815 and with an output providing a current supply to other functional modules. As further illustrated, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

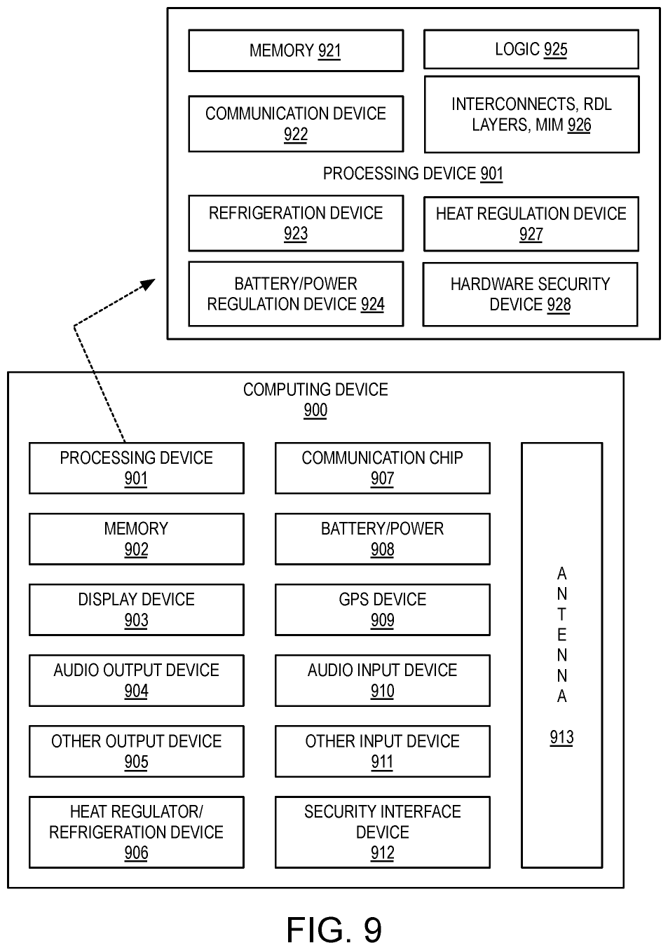

FIG. 9 is a block diagram of a cryogenically cooled computing device 900 in accordance with some embodiments. For example, one or more components of computing device 900 may include any of the devices or structures discussed elsewhere herein. A number of components are illustrated in FIG. 9 as included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled.

Computing device 900 may include a processing device 901 (e.g., one or more processing devices). As used herein, the term processing device or processor indicates a device that processes electronic data from registers and/or memory to transform that electronic data into other electronic data that may be stored in registers and/or memory. Processing device 801 may include a memory 921, a communication device 922, a refrigeration/active cooling device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 901 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 921 includes memory that shares a die with processing device 902. This memory may be used as cache memory and may include embedded dynamic random-access memory (eDRAM) or spin transfer torque magnetic random-access memory (STT-M RAM).

Computing device 900 may include a heat regulation/refrigeration device 906. Heat regulation/refrigeration device 906 may maintain processing device 902 (and/or other components of computing device 900) at a predetermined low temperature during operation. This predetermined low temperature may be any temperature discussed elsewhere herein.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 907 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 907 may operate in accordance with other wireless protocols in other embodiments. Computing device 900 may include an antenna 913 to facilitate wireless communications and/or to receive other wireless communications (such as AM or FM radio transmissions).

In some embodiments, communication chip 907 may manage wired communications, such as electrical, optical, or any other suitable communication protocols (e.g., the Ethernet). As noted above, communication chip 907 may include multiple communication chips. For instance, a first communication chip 907 may be dedicated to shorter-range wireless communications such as Wi-Fi or Bluetooth, and a second communication chip 907 may be dedicated to longer-range wireless communications such as GPS, EDGE, GPRS, CDMA, WiMAX, LTE, EV-DO, or others. In some embodiments, a first communication chip 907 may be dedicated to wireless communications, and a second communication chip 907 may be dedicated to wired communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a global positioning system (GPS) device 909 (or corresponding interface circuitry, as discussed above). GPS device 909 may be in communication with a satellite-based system and may receive a location of computing device 900, as known in the art.

Computing device 900 may include another output device 905 (or corresponding interface circuitry, as discussed above). Examples include an audio codec, a video codec, a printer, a wired or wireless transmitter for providing information to other devices, or an additional storage device.

Computing device 900 may include another input device 911 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, managing access lists, malware detection, or spyware detection.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

In first examples, an integrated circuit (IC) device comprises a first IC die bonded to a first region of a host substrate, wherein a first edge the first IC die has a first sidewall slope relative to a plane of the host substrate. The IC device comprises a second IC die bonded to a second region of the host substrate. The second IC die comprises a second edge adjacent to the first edge of the first IC die. The IC device comprises a fill within a space between the first and second IC dies. The fill comprises two or more layers of inorganic material, and an interface between a first of the layers and a second of the layers has a second sidewall slope that is smaller than the first sidewall slope.

In second examples, for any of the first examples a difference between the first and second sidewall slopes is at least 10°.

In third examples, for any of the first through second examples the first sidewall slope is at least 90° and wherein the second sidewall slope is less than 80°.

In fourth examples, for any of the first through third examples the first layer comprises predominantly silicon and oxygen.

In fifth examples, for any of the fourth examples the first and second layers have substantially the same composition.

In sixth examples, for any of the fourth examples the first layer has a first composition and the second layer has a second composition, different than the first composition.

In seventh examples, for any of the fourth examples the second layer has higher nitrogen content than the first layer.

In eighth examples, for any of the seventh examples the second layer comprises silicon and at least one of oxygen and nitrogen.

In ninth examples, for any of the first examples the fill comprises an interface layer between the first layer and the host substrate, and wherein the adhesion layer has a different composition than the first layer.

In tenth examples, for any of the ninth examples the interface layer has a greater nitrogen content and greater thickness conformality than the first layer.

In eleventh examples, for any of the first through tenth examples one or both of the first IC die and the second IC die is a die within a multi-die stack or within a multi-chip composite structure comprising a base die and one or more top dies gap-filled with an inorganic dielectric material.

In twelfth examples, for any of the first through eleventh examples the first edge is a perimeter edge of the first IC die, the second edge is a perimeter edge of the second IC die, a first portion of the first layer surrounds the first and second edges, and the second layer is within a recess that surrounds the first portion of the first layer.

In thirteenth examples, for any of the first through twelfth examples a surface of the fill is substantially co-planar with a surface of at least one of the first or second IC dies, and a structural member is bonded to the surface of the fill and bonded to the surface of at least one of the first or second IC die.

In fourteenth examples, for any of the thirteenth examples the structural member is silica glass or substantially monocrystalline silicon.

In fifteenth examples, a system comprises a host component, a composite integrated circuit (IC) die package attached to the host component. The composite IC device comprises a host substrate, a first IC die bonded to a first region of the host substrate. A first edge the first IC die has a first sidewall slope relative to a plane of the host substrate. The composite comprises a second IC die bonded to a second region of the host substrate. The second IC die comprises a second edge adjacent to the first edge of the first IC die. The composite comprises a fill within a space between the first and second IC dies. The fill comprises two or more layers of inorganic material and an interface between a first of the layers and a second of the layers has a second sidewall slope that is less than the first sidewall slope. The system comprises a structural member bonded to the surface of the fill and bonded to the surface of at least one of the first or second IC die.

In sixteenth examples, for any of the fifteenth examples, the system comprises a power supply coupled to provide power to the composite IC die package through the host component.

In seventeenth examples, for any of the fifteenth through sixteenth examples the host substrate is coupled to the host component through a plurality of first solder interconnects.

In eighteenth examples, for any of the fifteenth through seventeenth examples the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry. The second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

In nineteenth examples, a method of forming an integrated circuit (IC) device comprises bonding a first IC die to a first region of the host substrate. A first edge the first IC die has a first sidewall slope relative to a plane of the host substrate. The method comprises bonding a second IC die to a second region of the host substrate with a second edge of the second IC die adjacent to the first edge of the first IC die. The method comprises depositing a first layer of inorganic material within a space between the first and second IC dies. The method comprises decreasing a sidewall slope of the first layer to less than the first sidewall slope or decreasing an aspect ratio of the space by removing a partial thickness the first layer of inorganic material. The method comprises depositing a second layer of inorganic material over the first layer and within the space between the first and second IC dies.

In twentieth examples, for any of the nineteenth examples the method further comprises planarizing the second layer with a surface of at least one of the first or second IC dies.

In twenty-first examples, for any of the nineteenth through twentieth examples depositing the first layer comprises depositing a compound of predominantly silicon and oxygen with a plasma enhanced chemical vapor deposition process employing one or more precursors.

In twenty-second examples, for any of the nineteenth through twenty-first examples depositing the second layer comprises the plasma enhanced chemical vapor deposition process employing the one or more precursors.

In twenty-third examples, for any of the nineteenth through twenty-second examples removing comprises a plasma etch process, a mechanical grinding, or a chemical mechanical polishing.

In twenty-fourth examples, for any of the nineteenth through twenty-third examples bonding the first and second IC dies further comprises forming interdiffused metallurgical bonds between metallization features of the IC dies and metallization features of the host substrate.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) device, comprising:
a first IC die bonded to a first region of a host substrate, wherein a first edge the first IC die has a first sidewall slope relative to a plane of the host substrate;
a second IC die bonded to a second region of the host substrate, wherein the second IC die comprises a second edge adjacent to the first edge of the first IC die; and
a fill within a space between the first and second IC dies, wherein the fill comprises two or more layers of inorganic material, and wherein an interface between a first of the layers and a second of the layers has a second sidewall slope that is smaller than the first sidewall slope.

2. The IC device of claim 1, wherein a difference between the first and second sidewall slopes is at least 10°.

3. The IC device of claim 2, wherein the first sidewall slope is at least 90° and wherein the second sidewall slope is less than 80°.

4. The IC device of claim 1, wherein the first layer comprises predominantly silicon and oxygen.

5. The IC device of claim 4, wherein first and second layers have substantially the same composition.

6. The IC device of claim 4, wherein the first layer has a first composition and the second layer has a second composition, different than the first composition.

7. The IC device of claim 6, wherein the second layer has higher nitrogen content than the first layer.

8. The IC device of claim 7, wherein the second layer comprises silicon and at least one of oxygen and nitrogen.

9. The IC device of claim 1, wherein the fill comprises an interface layer between the first layer and the host substrate, and wherein the adhesion layer has a different composition than the first layer.

10. The IC device of claim 9, wherein the interface layer has a greater nitrogen content and greater thickness conformality than the first layer.

11. The IC device of claim 1, wherein one or both of the first IC die and the second IC die is a die within a multi-die stack or within a multi-chip composite structure comprising a base die and one or more top dies gap-filled with an inorganic dielectric material.

12. The IC device of claim 1, wherein:
the first edge is a perimeter edge of the first IC die;
the second edge is a perimeter edge of the second IC die;
a first portion of the first layer surrounds the first and second edges; and
the second layer is within a recess that surrounds the first portion of the first layer.

13. The IC device of claim 1, wherein:
a surface of the fill is substantially co-planar with a surface of at least one of the first or second IC dies; and
a structural member is bonded to the surface of the fill and bonded to the surface of at least one of the first or second IC die.

14. The IC device of claim 13, wherein the structural member is silica glass or substantially monocrystalline silicon.

15. A system comprising:
a host component;
a composite integrated circuit (IC) die package attached to the host component, the composite IC device comprising:
a host substrate;
a first IC die bonded to a first region of the host substrate, wherein a first edge the first IC die has a first sidewall slope relative to a plane of the host substrate;
a second IC die bonded to a second region of the host substrate, wherein the second IC die comprises a second edge adjacent to the first edge of the first IC die;
a fill within a space between the first and second IC dies, wherein the fill comprises two or more layers of inorganic material, and wherein an interface between a first of the layers and a second of the layers has a second sidewall slope that is less than the first sidewall slope; and
a structural member is bonded to the surface of the fill and bonded to the surface of at least one of the first or second IC die.

16. The system of claim 15, further comprising:
a power supply coupled to provide power to the composite IC die package through the host component.

17. The system of claim 15, wherein the host substrate is coupled to the host component through a plurality of first solder interconnects.

18. The system of claim 15, wherein:
the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry; and
the second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

19. A method of forming a composite integrated circuit (IC) device, the method comprising:
bonding a first IC die to a first region of the host substrate, wherein a first edge the first IC die has a first sidewall slope relative to a plane of the host substrate;
bonding a second IC die to a second region of the host substrate with a second edge of the second IC die adjacent to the first edge of the first IC die;
depositing a first layer of inorganic material within a space between the first and second IC dies;
decreasing a sidewall slope of the first layer to less than the first sidewall slope or decreasing an aspect ratio of the space by removing a partial thickness the first layer of inorganic material; and
depositing a second layer of inorganic material over the first layer and within the space between the first and second IC dies.

20. The method of claim 19, further comprising planarizing the second layer with a surface of at least one of the first or second IC dies.

21. The method of claim 19, wherein depositing the first layer comprises depositing a compound of predominantly silicon and oxygen with a plasma enhanced chemical vapor deposition process employing one or more precursors.

22. The method of claim 21, wherein depositing the second layer comprises the plasma enhanced chemical vapor deposition process employing the one or more precursors.

23. The method of claim 19, wherein the removing comprises:
a plasma etch process;
a mechanical grinding; or
a chemical mechanical polishing.

24. The method of claim 19, wherein:
bonding the first and second IC dies further comprises forming interdiffused metallurgical bonds between metallization features of the IC dies and metallization features of the host substrate.
